(19) United States
(12) Patent Application Publication
(10) Pub. No.: US 2009/0039479 A1
(43) Pub. Date: Feb. 12, 2009

(54) MODULE FOR INTEGRATING PERIPHERAL CIRCUIT AND A MANUFACTURING METHOD THEREOF

(75) Inventors: CHUNG-ER HUANG, TAIPEI (TW); YUEH-CHENG LEE, TAIPEI (TW)

Correspondence Address: ROSENBERG, KLEIN & LEE, 3458 ELLICOTT CENTER DRIVE-SUITE 101, ELLICOTT CITY, MD, 21043, US

(73) Assignee: AZUREWAVE TECHNOLOGIES, INC., TAIPEI (TW)

(21) Appl. No.: 11/861,773

(22) Filed: Sep. 26, 2007

(30) Foreign Application Priority Data
Aug. 8, 2007 (TW) 96129223

(51) Int. Cl. H01L 23/66; H01L 21/60

(52) U.S. Cl. 257/664; 438/107; 257/E21.506; 257/E23.141

(57) ABSTRACT

A module for integrating peripheral circuit includes a silicon chip substrate, at least one peripheral circuit unit, and at least one main circuit unit. The peripheral circuit unit is integrated in the silicon chip substrate via a semiconductor manufacturing process. The main circuit unit is mounted on the surface of the silicon chip substrate and is electrically connected with the peripheral circuit unit for transmitting the signal. Thereby, the dimension of the module is reduced.

### BACKGROUND OF THE INVENTION

1. Field of the Invention

The present invention relates to a module for integrating peripheral circuit and a manufacturing method thereof. In particular, this invention relates to a module and a manufacturing method thereof that integrates peripheral circuit into a substrate.

2. Description of the Related Art

As the technology has been rapidly developed, a variety of devices are developed by using the technology and are continuously progressed. Because the functions of the devices are rapidly added, most devices are implemented by a modulated method. However, although the functions of the devices can be increased by integrating a lot of functional modules, how to design a multiple function device with a small dimension is a concerned topic.

In the semiconductor manufacturing process, a high level technology is used to manufacture a small chip or component. Therefore, the module manufacturer can design a functional module with a small dimension, and the device can be efficiently and fully developed.

Currently, most modules use the PCB, FR-4, or BT substrate as a carrier. All chips and components are mounted onto the surface of the carrier by using a surface mounted technology (SMT). Therefore, the substrate is merely used as a carrier and is used for connecting the circuit. The structure of the substrate is a multiple-layered structure and is only used for the circuit layout.

Taking the RF system module as an example, in order to have multiple functions, WLAN module usually is integrated with the Bluetooth module, or the GPS module. However, the required peripheral circuits increases. When all components for each of the circuits are mounted onto the substrate, the dimension of the whole module increases. At the same times, it is difficult for the designer to design a signal anti-interfered circuit within the substrate, and the characteristic of the circuit may be affected.

### SUMMARY OF THE INVENTION

One particular aspect of the present invention is to use a variety of substrates and the semiconductor manufacturing technology to integrate the peripheral circuits onto a substrate and reduce the dimension of the whole module. Furthermore, because the peripheral circuits are very close to the main circuit, the performance of the module is substantially enhanced.

The present invention provides a module for integrating peripheral circuit. The module for integrating peripheral circuit includes a silicon chip substrate, at least one peripheral circuit unit, and at least one main circuit unit. The peripheral circuit unit is integrated in the silicon chip substrate via a semiconductor manufacturing process. The main circuit unit is mounted on the surface of the silicon chip substrate and is electrically connected with the peripheral circuit unit for transmitting the signal.

The present invention also provides a manufacturing method for the module that integrates the peripheral circuit. The steps include providing at least one peripheral circuit unit. Next, a semiconductor manufacturing process is used to integrate the peripheral circuit unit into a silicon chip substrate. Finally, at least one main circuit unit is mounted on the surface of the silicon chip substrate and is electrically connected with the peripheral circuit unit. Thereby, the dimension of the whole module is reduced.

For further understanding of the invention, reference is made to the following detailed description illustrating the embodiments and examples of the invention. The description is only for illustrating the invention and is not intended to be considered limiting of the scope of the claim.

### BRIEF DESCRIPTION OF THE DRAWINGS

The drawings included herein provide a further understanding of the invention. A brief introduction of the drawings is as follows:

FIG. 1 is a perspective schematic diagram of the module for integrating peripheral circuit of the present invention;

FIG. 1A is a block diagram of the clock signal generation circuit connecting with the silicon chip substrate;

FIG. 2A is a top view of the through hole of the module for integrating peripheral circuit of the present invention;

FIG. 2B is a cross-sectional view of the through hole in FIG. 2A; and

FIG. 3 is a flow chart of the manufacturing method for the module that integrates the peripheral circuit.

### DETAILED DESCRIPTION OF THE PREFERRED EMBODIMENTS

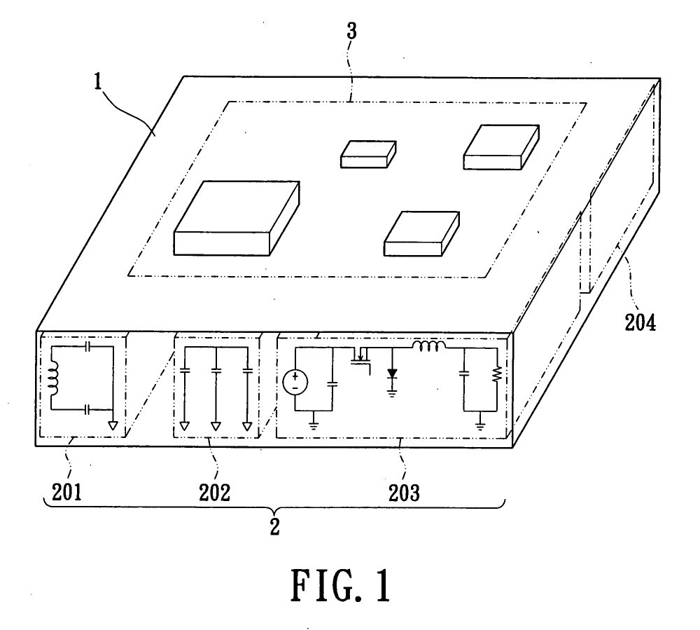

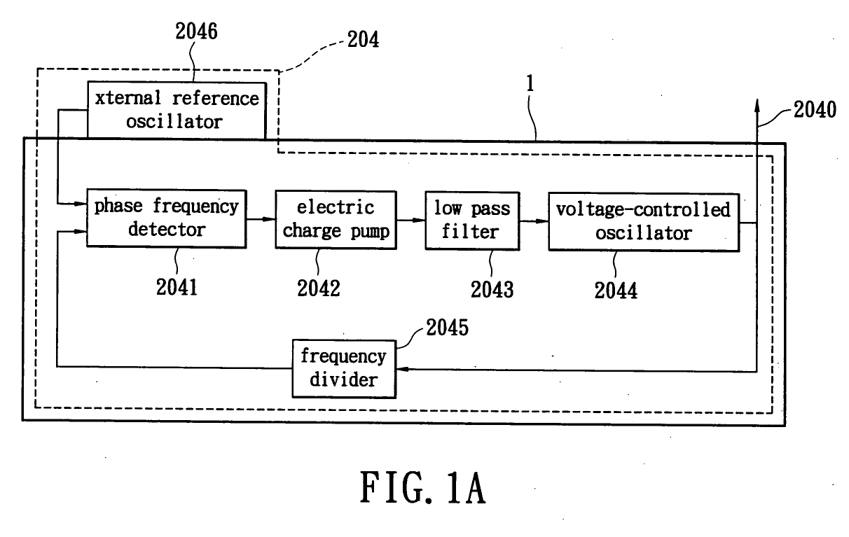

Reference is made to FIG. 1, which shows a perspective schematic diagram of the module for integrating peripheral circuit of the present invention. The module for integrating peripheral circuit includes a silicon chip substrate 1, at least one peripheral circuit unit 2, and at least one main circuit unit 3. The peripheral circuit unit 2 is integrated in the silicon chip substrate 1 via a semiconductor manufacturing process. The main circuit unit 3 is mounted on the surface of the silicon chip substrate 1, such as using the surface mounted technology (SMT), and is electrically connected with the peripheral circuit unit 2 that has been integrated in the silicon chip substrate 1 for transmitting the signal.

The peripheral circuit unit 2 can be an impedance matching circuit 201, a capacitor filtering circuit 202, a voltage-converting circuit 203, and a clock signal generation circuit 204, shown in FIG. 1. Furthermore, the peripheral circuit unit 2 can be a memory storage circuit, a power management circuit, an interface converting circuit, or an antenna phase converting circuit, etc. In order to illustrate the connecting relationship for integrating the peripheral circuit unit 2 into the silicon chip substrate 1, please refer to FIG. 1 that is a block diagram of the clock signal generation circuit connecting with the silicon chip substrate. In this embodiment, the fixed components in the clock signal generation circuit 204 of the frequency synthesizer are integrated into the silicon chip substrate 1. The clock signal generation circuit 204 originally includes a phase frequency detector 2041, an electric charge pump 2042, a low pass filter 2043, a voltage-controlled oscillator 2044, a frequency divider 2045, and an external reference oscillator 2046. In this embodiment, the phase frequency detector 2041, the electric charge pump 2042, the low pass filter 2043, the voltage-controlled oscillator 2044, and the frequency divider 2045 are integrated into the silicon chip substrate 1 to form a phase lock loop for outputting the clock signal 2040. Furthermore, because the external reference oscillator 2046 that generates a reference frequency for the phase lock loop may be different due to different applications, the external reference oscillator 2046 is designed on the surface of the silicon chip substrate 1. The required components for the external reference oscillator 2046 are mounted on the surface of the silicon chip substrate 1 according to the applications.

In order to apply this invention to a variety of applications, the sort of the peripheral circuit is not limited to above. One or more than one circuit is selected to implement the application. Furthermore, the sort of the peripheral circuit is not used to limit the scope of the present invention.

Because the peripheral circuit unit 2 already has been integrated into the silicon chip substrate 1 via a semiconductor manufacturing process, the circuit layout between the main circuit unit 3 and the peripheral circuit unit 2 can be implemented by a redistribution layer (RDL). The main circuit unit 3 mounted on the silicon chip substrate 1 is electrically connected with the peripheral circuit unit 2 integrated into the silicon chip substrate 1 by adjusting the input/output locations of the components. The signal quality and stability between components are enhanced.

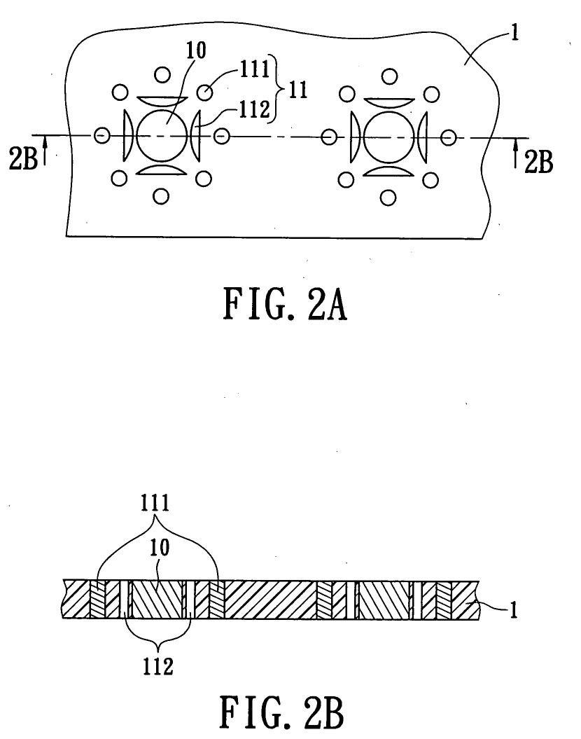

In order to prevent the signals transmitted between the main circuit unit 3 and the peripheral circuit unit 2 from being interfered by noise, or from being attenuated, such as the signal in a high frequency wireless RF circuit is easily interfered by the environment, and the high frequency signal easily radiates and attenuates, the high frequency signal needs to be transmitted by a noiseless path. Reference is made to FIGS. 2A and 2B, which show a top view and a cross-sectional view of the through hole of the module for integrating peripheral circuit of the present invention. If a noiseless signal line 10 needs to be placed on the silicon chip substrate 1, a sheltered grounding structure 11 is disposed around the signal line 10. Thereby, the signal in the signal line 10 will not be interfered by noise, and the signal in the signal line 10 will not escape to outside. As shown in FIGS. 2A and 2B, the sheltered grounding structure 11 is implemented by a two-layered structure, including the metal-plated through hole 111 and the hollow parallel through hole 112, to shelter the signal line 10. Alternatively, only the metal-plated through hole 111 or the hollow parallel through hole 112 is used for sheltering the signal line 10. When a two-layered structure is designed as the sheltered grounding structure 11, the order of the layers is not limited to above.

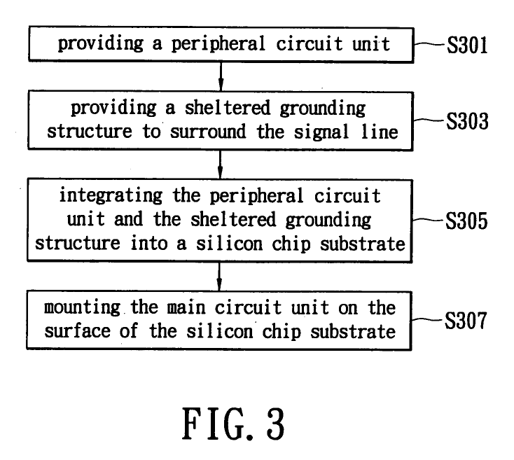

Reference is made to FIG. 3, which shows a flow chart of the manufacturing method for the module that integrates the peripheral circuit. Firstly, according to the requirements of the module, a peripheral circuit unit 2 that needs to be integrated is provided (S301). Next, according to the signal quality requirement of the peripheral circuit unit 2, a sheltered grounding structure 11 disposed around the signal line 10 is provided (S303). A semiconductor manufacturing process is used to integrate the peripheral circuit unit 2 and the sheltered grounding structure 11 into a silicon chip substrate 1 (S305). Finally, the main circuit unit 3 is mounted on the surface of the silicon chip substrate 1 and is electrically connected with the peripheral circuit unit 2 in the silicon chip substrate 1 (S307). Thereby, the module that prevents the signal from be interfered, restrains signal attenuation, has multiple functions and is small is finished.

The semiconductor manufacturing process is a series of manufacturing processes, including photolithography, rapid thermal processing, chemical vapor disposition (CVD), ion implantation, etching, etc, such as the silicon wafer is processed by the above processes to become the silicon chip substrate 1 with circuit.

The present invention uses a variety of substrates and the semiconductor manufacturing technology to integrate the peripheral circuits onto a substrate and reduce the dimension of the whole module. Furthermore, the present invention has the following characteristics:

1. The circuit characteristic of the module is enhanced. Because the peripheral circuit unit is very close the main circuit unit, the signal attenuation is avoided when the signal is transmitted via a long distance line. The circuit performance of the module is substantially enhanced.

2. The module temperature is reduced. Because the heat conductivity of the silicon chip substrate is good, the silicon chip substrate used as a carrier can reduce the heat generated by the whole module.

3. The cost is reduced. Because part or all of the peripheral circuit units are integrated into the silicon chip substrate, it does not need to use a high level manufacturing process due to the silicon chip substrate has a large area. All of the peripheral circuit units are manufactured in the silicon chip substrate by a low level manufacturing process (such as 0.5 micrometer manufacturing process). The cost is substantially reduced.

The description above only illustrates specific embodiments and examples of the invention. The invention should therefore cover various modifications and variations made to the herein-described structure and operations of the invention, provided they fall within the scope of the invention as defined in the following appended claims.

What is claimed is:

1. A module for integrating peripheral circuit, comprising:
a silicon chip substrate;
at least one peripheral circuit unit integrated in the silicon chip substrate via a semiconductor manufacturing process; and
at least one main circuit unit mounted on a surface of the silicon chip substrate and electrically connected with the peripheral circuit unit for transmitting the signal.

2. The module for integrating peripheral circuit as claimed in claim 1, wherein the peripheral circuit unit is an impedance matching circuit, a capacitor filtering circuit, a voltage-converting circuit, a memory storage circuit, a power management circuit, an interface converting circuit, a clock signal generation circuit, and/or an antenna phase converting circuit.

3. The module for integrating peripheral circuit as claimed in claim 1, wherein the main circuit unit and the peripheral circuit unit are connected together via a redistribution layer.

4. The module for integrating peripheral circuit as claimed in claim 1, wherein a signal line between the main circuit unit and the peripheral circuit unit in the silicon chip substrate is disposed with a sheltered grounding structure.

5. The module for integrating peripheral circuit as claimed in claim 4, wherein the sheltered grounding structure is a metal-plated through hole and/or a hollow parallel through hole.

6. A manufacturing method for the module that integrates the peripheral circuit as claimed in claim 1, the steps comprising:
providing the peripheral circuit unit;
using the semiconductor manufacturing process to integrate the peripheral circuit unit into the silicon chip substrate; and
mounting the main circuit unit is mounted on a surface of the silicon chip substrate to electrically connected with the peripheral circuit unit.

7. The manufacturing method for the module that integrates the peripheral circuit as claimed in claim 6, wherein the peripheral circuit unit is an impedance matching circuit, a capacitor filtering circuit, a voltage-converting circuit, a memory storage circuit, a power management circuit, an interface converting circuit, a clock signal generation circuit, and/or an antenna phase converting circuit.

8. The manufacturing method for the module that integrates the peripheral circuit as claimed in claim 6, wherein the main circuit unit and the peripheral circuit unit are connected together via a redistribution layer.

9. The manufacturing method for the module that integrates the peripheral circuit as claimed in claim 6, wherein the step of using the semiconductor manufacturing process to integrate the peripheral circuit unit into the silicon chip substrate further comprises a step of disposing a sheltered grounding structure around a signal line between the main circuit unit and the peripheral circuit unit.

10. The manufacturing method for the module that integrates the peripheral circuit as claimed in claim 9, wherein the sheltered grounding structure is a metal-plated through hole and/or a hollow parallel through hole.
